(19) United States
(12) Patent Application Publication
(10) Pub. No.: US 2026/0124691 A1
(43) Pub. Date: May 7, 2026

(54) LASER COMPRESSION BONDING DEVICE

(71) Applicant: STATS ChipPAC Management Pte. Ltd., Singapore (SG)

(72) Inventors: JongChan PARK, Incheon (KR); HyungSuk MIN, Incheon (KR)

(21) Appl. No.: 19/377,020

(22) Filed: Nov. 2, 2025

(30) Foreign Application Priority Data
Nov. 1, 2024 (CN) 202411553348.3

(51) Int. Cl. H01L 23/00; B23K 1/005; B23K 101/40

(52) U.S. Cl. CPC B23K 1/0056; B23K 2101/40; H10W 72/07141; H10W 72/07152; H10W 72/07232; H10W 72/07235

(57) ABSTRACT

A laser compression bonding device comprises: a carrier for placing a substrate; a transparent compression head for holding and displacing an electronic component, wherein the transparent compression head comprises a central portion for pressing the electronic component against the substrate via a solder material when the electronic component is placed on the substrate via the solder material, and a peripheral portion surrounding the central portion; a laser source for emitting a laser beam towards the carrier at least through the central portion of the transparent compression head to heat the solder material such that the electronic component is bonded onto the substrate via the solder material; and a heat spreader attached to the peripheral portion of the transparent compression head, wherein the heat spreader comprises a liquid channel for containing liquid that flows in the liquid channel to exchange heat with the transparent compression head.

### TECHNICAL FIELD

The present application generally relates to semiconductor technology, and more particularly, to a laser compression bonding device and a method for using the same.

### BACKGROUND OF THE INVENTION

Laser compression bonding (LCB) or soldering processes have been used to replace conventional massive reflowing processes in forming semiconductor packages, because during the laser compression soldering process thermal stresses within the semiconductor packages can be reduced. However, LCB tools are generally made of transparent materials such as bulk quartz or the like, which have low thermal conductivities. Heat may accumulate in the LCB tool during the bonding processes and may undesirably increase a temperature of the LCB tool.

Therefore, a need exists for a new laser compression bonding device.

### SUMMARY OF THE INVENTION

An objective of the present application is to provide a laser compression bonding device with an improved heat dissipation performance.

According to an aspect of the present application, a laser compression bonding device is provided. The laser compression bonding device comprises: a carrier for placing a substrate; a transparent compression head for holding and displacing an electronic component, wherein the transparent compression head comprises a central portion for pressing the electronic component against the substrate via a solder material when the electronic component is placed on the substrate via the solder material, and a peripheral portion surrounding the central portion; a laser source for emitting a laser beam towards the carrier at least through the central portion of the transparent compression head to heat the solder material such that the electronic component is bonded onto the substrate via the solder material; and a heat spreader attached to the peripheral portion of the transparent compression head, wherein the heat spreader comprises a liquid channel for containing liquid that flows in the liquid channel to exchange heat with the transparent compression head.

According to another aspect of the present application, a laser compression bonding method is provided. The method comprises: placing a substrate on a carrier; placing by a transparent compression head an electronic component on the substrate via a solder material; pressing the electronic component against the substrate by the transparent compression head and irradiating to the carrier a laser beam from a laser source through the central portion of the transparent compression head to bond the electronic component onto the substrate via the solder material; and injecting a liquid into a heat spreader attached to a peripheral portion of the transparent compression head to cool the transparent compression head, wherein the peripheral portion is surrounding the central portion and the heat spreader comprises a liquid channel; drawing the liquid from the liquid channel after heat exchange between the liquid and the transparent compression head.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates changes in temperature of an LCB tool and an electronic component held by the LCB tool under different conditions.

FIGS. 2a and 2b illustrate a laser compression bonding device according to an embodiment of the present application.

FIGS. 3a to 3c illustrate a laser compression bonding method according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, laser compression bonding (LCB) tools are usually made of transparent materials such as quartz, fused silica, sapphire or ZnSe, which have low thermal conductivities but high heat capacities. The thermal characteristics of the transparent materials increase difficulty in heating and cooling the LCB tools compared with conventional metal compression tools. In particular, it is noted by the inventors of the present application that the LCB tools may undergo a slow but continuous temperature increase if multiple cycles of LCB processes are performed by the same LCB tool.

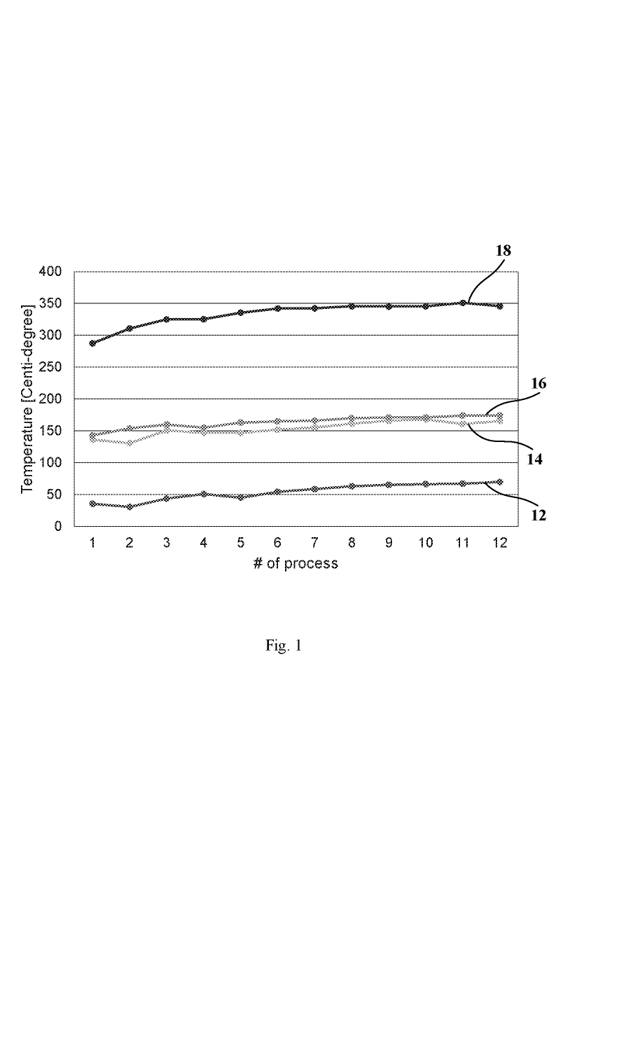

FIG. 1 illustrates changes in temperature of an LCB tool and an electronic component held by the LCB tool under different conditions. As shown in FIG. 1, curve 12 depicts that the temperature at a surface of the LCB tool before bonding increases from about 37 centi-degrees to 76 centi-degrees after 12 cycles of LCB processes; curve 14 depicts that the peak temperature at the surface of the LCB tool during bonding increases from about 130 centi-degrees to about 170 centi-degrees; curve 16 depicts that the temperature of the electronic component before bonding increases from 142 centi-degrees to 178 centi-degrees; and curve 18 depicts that the peak temperature of the electronic component during bonding increases from 282 centi-degrees to 345 centi-degrees. The significant temperature changes of the LCB tool and the electronic component may adversely affect the performance especially stability of the LCB tool because the temperatures of the solder materials and the devices to be bonded together may increase as well, introducing undesired deviations into the bonding processes implemented by LCB tools. Furthermore, the undesired temperature increases may also make the devices processed by the LCB tools easier to warp, which may lead to non-wetting or other issues.

In order to address the above issue, a specific heat spreader is proposed to be incorporated into an LCB tool to cool down the LCB tool. The heat spreader utilizes a liquid coolant such as water to transfer heat from the LCB tool to the external environment. The liquid coolant may have a greater thermal capacity than air or other gaseous mediums, and thus can cool the LCB tool more efficiently and maintain the temperature of the LCB tool within a range which is acceptable to LCB processes.

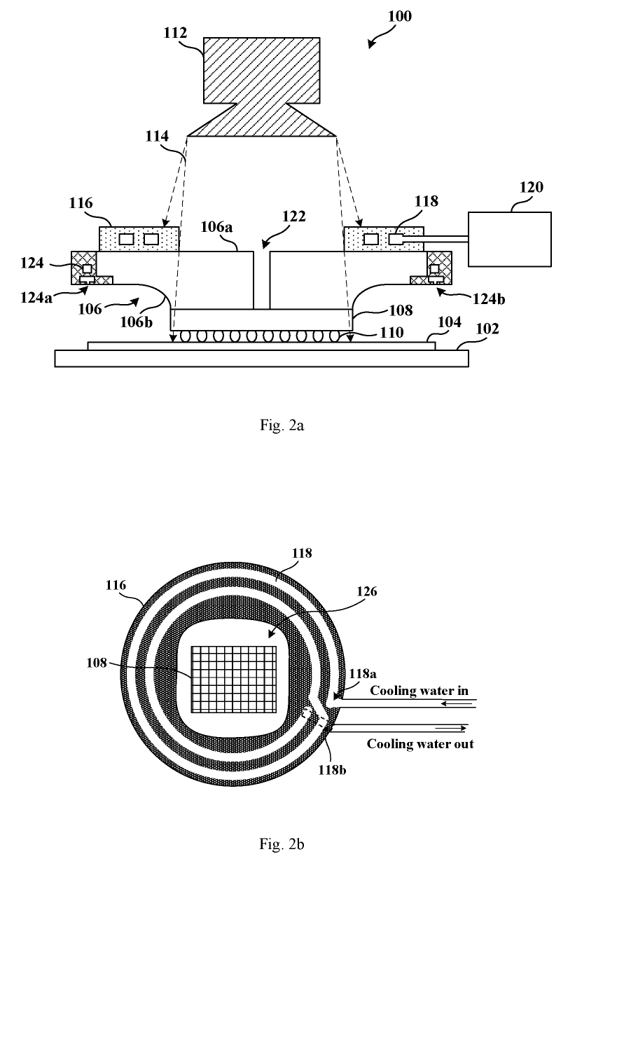

FIGS. 2a and 2b illustrate a laser compression bonding device 100 according to an embodiment of the present application. The laser compression bonding device 100 can generate a laser beam which may be used to bond one or more electronic components such as semiconductor chips onto a substrate such as a printed circuit board, an interposer, etc. by heating a solder material between the electronic components and the substrate. In particular, the solder material may be deposited onto either or both of the electronic components and the substrate prior to the bonding process, and then during the bonding process the solder material may be melted by energy delivered by the laser beam and later solidify as solder bumps to bond the electronic components with the substrate. Besides delivering the laser energy to the solder material, the laser compression bonding device 100 also applies a pressure to the solder material to assist the bonding between the electronic components and the substrate.

As shown in FIG. 2a, the laser compression bonding device 100 includes a carrier 102 such as a carrier platform for placing a substrate 104, and a transparent compression head 106 which may hold and displace an electronic component 108 that is to be bonded onto the substrate 104. In particular, the transparent compression head 106 may include a back surface on which the electronic component 108 is attached. The back surface may face towards the substrate 104 and the carrier 102 thereunder when the transparent compression head 106 moves the electronic component 108 onto the substrate 104 via a solder material 110. In some examples, the electronic component 108 may have at its back side a first set of conductive patterns such as contact pads, and the substrate 104 may have at its front side a second set of conductive patterns such as contact pads which may have a layout identical to or similar as that of the first set of conductive patterns of the electronic component 108. The solder material 110 may be formed in advance on either or both of the two sets of conductive patterns, such that with the bonding process, the solder material 110 can bond the two sets of conductive patterns together and therefore electrically and mechanically connect the electronic component 108 with the substrate 104. In some embodiments, the electronic component 108 may be a semiconductor chip, while in some other embodiments, the electronic component 108 may be a semiconductor package or other similar devices or modules.

In the embodiment shown in FIG. 2a, the transparent compression head 106 has a convex back surface. In particular, the back surface of the transparent compression head 106 in a central portion 106a, i.e., where the electronic component 108 is attached, is lower and closer to the carrier 102, compared to the back surface of the transparent compression head 106 in a peripheral portion 106b which surrounds the central portion 106a. In that case, when the transparent compression head 106 presses the electronic component 108 against the substrate 104 via the solder material 110, the back surface in the central portion 106a may be in contact with the electronic component 108 while the back surface in the peripheral portion 106b may be farther away from the substrate 104 and the carrier 102, leaving enough space between the carrier 102 and the transparent compression head 106 which can avoid undesired conflicts that may contaminate or even damage the transparent compression head 106. However, it can be appreciated that the transparent compression head 106 may have other shaped back surfaces. For example, the back surface of the transparent compression head 106 may be flat, both in the central portion and in the peripheral portion.

In some embodiments, at least one through hole 122 may be formed in the transparent compression head 106, which passes through the central portion 106a to apply a vacuum pressure to the electronic component 108 to hold the electronic component 108 firmly. For example, a vacuum source may be fluidly coupled to the through hole 122 to supply the vacuum pressure. The vacuum pressure may be applied during the movement of the electronic component 108 with the transparent compression head 106, but may be released when the electronic component 108 is in place on the substrate 104, for example, during the bonding process.

The transparent compression head 106 may be mechanically coupled to a driver or an actuator (not shown), which can move the transparent compression head 106 automatically under the control of a controller, a host device or a server, or manually under the control of a user. Furthermore, when the electronic component 108 is placed on the substrate 104 via the solder material 110, the driver or the actuator may apply a force to the transparent compression head 106, which in turn, generates a compression pressure at the solder material 110 to assist the bonding process.

Still referring to FIG. 2a, the laser compression bonding device 100 further includes a laser source 112, which can generate a laser beam 114 that is used to provide laser energy to reflow the solder material 110. In particular, the laser source 112 may be placed above the transparent compression head 106 and facing towards the front surface of the transparent compression head 106. During the laser compression bonding process, the laser beam 114 may be emitted from the laser source 112 towards the carrier 102 at least through the central portion 106a of the transparent compression head 106 to heat the solder material 110. A sufficient amount of laser energy may be applied to the solder material 110 during the bonding process, to melt and reflow the solder material 110. When the laser source 112 is turned off, the melted solder material 110 may solidify into solder bumps between the substrate 104 and the electronic component 108. In this way, the electronic component 108 can be bonded onto the substrate 104 via the solder bumps after the bonding process.

As aforementioned, the laser energy that is transformed into heat may accumulate in the transparent compression head 106 and increase the temperature of the transparent compression head 106, which is undesired for the subsequent bonding process. The transparent compression head 106 can be made of transparent materials such as quartz, fused silica, sapphire or ZnSe, which have low thermal conductivities that are adverse to heat dissipation. In that case, a heat spreader 116 is attached to the peripheral portion 106b of the transparent compression head 106 to cool the transparent compression head 106. The heat spreader 116 is in direct contact with the transparent compression head 106 to absorb heat from the transparent compression head 106. Although the heat spreader 116 may not be in direct contact with the central portion 106a through which the laser beam 114 passes, heat generated there can be transferred to the heat spreader 116 through the peripheral portion 106b and later dissipated to the external environment through the heat spreader 116. In some embodiments, the heat spreader 116 may have a smooth surface which can be attached to the transparent compression head 106 directly. The smooth surfaces of the heat spreader 116 and the transparent compression head 106 can ensure good contact therebetween, which facilitates heat transfer. In some other examples, an adhesive material such as a thermal interfacing material with a high thermal conductivity can be dispensed between the heat spreader 116 and the transparent compression head 106 to improve further the heat transfer performance.

In the embodiment shown in FIG. 2a, the heat spreader 116 is attached on the front surface of the transparent compression head 106, which may not occupy the space between the transparent compression head 106 and the substrate 104 or the carrier 102. In some examples, the heat spreader 116 may be alternatively attached on the back surface of the transparent compression head 106, for example, surrounding the central portion 106a and the electronic component 108. In some other examples, the heat spreader 116 may be attached on both of the front surface and the back surface of the transparent compression head 106. Generally the transparent compression head 106 may be shaped as a plate or a disc, and attaching the heat spreader 116 on the front surface or back surface of the transparent compression head 106 can allow for better contact between them and thus improve heat dissipation performance.

The heat spreader 116 may include a liquid channel 118, which contains liquid that can flow in the liquid channel 118, for example, from an external liquid supply 120 and back to the external liquid supply 120 or another liquid container, after heat exchange with the transparent compression head 106. Before flowing into the liquid channel 118, the liquid such as water or another cooling liquid may have a temperature lower than that that of the transparent compression head 106, and thus, heat can be transferred from the high-temperature transparent compression head 106 to the low-temperature liquid. In some preferred embodiments, a temperature difference between the liquid and the transparent compression head 106 may be greater than 70 centi-degrees, and preferably greater than 100 centi-degrees. For example, the liquid such as water may have a temperature around 20 centi-degrees before it is injected into the liquid channel 118. However, the difference in temperature between the heat spreader and the transparent compression head 106 should not be too big, as a big temperature difference may result in significant thermal stresses to the transparent compression head 106, which may damage or even break the transparent compression head 106. Also, it is not preferred to have a cooling liquid with a temperature lower than 5 centi-degrees as water vapor in the air or in the environment may be liquefied on an outer wall of the liquid channel 118, which may be undesired for the bonding process.

FIG. 2b illustrates an exemplary layout of the heat spreader 116 and the liquid channel 118 therein according to an embodiment of the present application. As shown in FIG. 2b, the heat spreader 116 may surround the electronic component 108. The heat spreader 116 may define at its center an aperture 126 that is aligned with the electronic component 108 and has a size slightly greater than that of the electronic component 108. In this way, the laser beam emitted from the laser source towards the electronic component 108 can pass through the heat spreader 116 to the electronic component 108 without being substantially blocked by the heat spreader 116. To ensure sufficient heat exchange between the heat spreader 116 and the transparent compression head, the liquid channel 118 may take a spiral shape with one or more loops extending about the aperture 126 and fluidly coupled together. For example, a liquid input 118a may be coupled to an outermost loop of the liquid channel 118 to receive the cooling liquid such as cooling water. After flowing through several inner loops of the liquid channel 118, the cooling liquid may flow out of the liquid channel 118 through a liquid outlet 118b that is coupled to an innermost loop of the liquid channel 118. Such looping of the liquid channel 118 can have the cooling liquid to flow from lower temperature regions or loops to higher temperature regions or loops and thus effectively absorb heat from the transparent compression head.

In the embodiment shown in FIGS. 2a and 2b, the heat spreader 116 has the aperture 126 which allows the laser beam 114 to pass therethrough and further to the bonding material 110 under the electronic component 108. In other words, there is no significant loss during the transmission of the laser beam 114 through the heat spreader 116. Accordingly, the heat spreader 116 may be formed of a non-transparent material such as metal or a transparent material such as quartz, glass, or polymer. In an example, the heat spreader 116 may be formed a non-transparent material, which may block the transmission of an outer portion of the laser beam 114 that is directed towards the peripheral portion of the substrate 104 without the solder material or even the peripheral portion of the carrier 102, rather than towards the electronic component 108. The non-transparent heat spreader 116 may act as an optical mask for the laser beam 114, and accordingly, the size of a light spot formed by the laser beam 114 on the electronic component 108 can be configured by the non-transparent heat spreader 116. The blocked portion of the laser energy may not reach the substrate 104 and thus may not be transformed into heat at the substrate 104 which is undesired and excessive from the perspective of cooling the transparent compression head 106. In an example, the non- transparent heat spreader 116 may be made of stainless steel with a surface coating such as nickel or chrome, or made of copper coated with nickel. However, it can be appreciated that many other materials with a high thermal conductivity can be used for the non-transparent heat spreader 116. In some embodiments, the heat spreader 116 may be removably attached onto the transparent compression head 106, and may be one of a set of heat spreaders with different sized apertures. In that case, a corresponding heat spreader may be selected from the set of heat spreaders, for example, based on the size of the electronic component 108 to be bonded onto the substrate 104. That is, the size of the heat spreader may be selected to minimize the undesired laser irradiation on the electronic component 108.

As mentioned above, in some other embodiments, the heat spreader 116 may be formed of a transparent material. In that case, as water or most cooling liquids are also transparent, the heat spreader 116 with the cooling liquid flowing therein is generally transparent to the laser beam 114. In some optional embodiments, each of the loops of the liquid channel 118 may have a cross section which may refract a portion of the laser beam 114, and accordingly, the combination of the loops of liquid channel 118 may act as a Fresnel lens that can focus the laser beam 114, for example, to the electronic component 108 rather than to the peripheral portion of the substrate 104 without the solder material 110. The refracted portion of the laser beam 114 may overlay with the remaining portion of the laser beam 114 onto the electronic component 108 to increase an intensity of laser energy applied to the electronic component 108 and the solder material 110. In this way, the energy of the laser beam 114 can be utilized more efficiently.

As liquids especially water have greater heat capacities than air or other gaseous mediums, the heat spreader 116 using liquids as coolants can effectively cool down the transparent compression head 108. In an example, with the heat spreader 116 mounted on the front surface of the transparent compression head 108, the temperature of the surface of the transparent compression head 108 before bonding can be maintained lower than 60 centi-degrees after tens of cycles of bonding processes, which is significantly lower than 76 centi-degrees if no such heat spreader is used for a conventional laser compression bonding device. In this way, the temperature of the transparent compression head 108 at the start of each bonding cycle can be maintained substantially the same, and all the devices processed by the laser compression bonding device 100 can undergo similar temperature profiles, thereby increasing the reliability of the bonding processes.

Still referring to FIG. 2a, besides the heat spreader 116, an airflow channel 124 may be attached to an outside edge of the transparent compression head 106. The airflow channel 124 is used to contain a cooling airflow for cooling the transparent compression head 106, which improves further the heat dissipation performance of the laser compression bonding device 100. In the embodiment, the airflow channel 124 may be similarly have one or more loops of airflow tubes such as vortex tubes that extend about the transparent compression head 106. The loops of the airflow channel 124 may be arranged vertically and close to the outside edge of the transparent compression head 106 to form a compact structure. In operation, the airflow channel 124 may receive a cooling airflow at an airflow inlet 124a from an external fan or the like, and after the airflow exchanges heat with the transparent compression head 106, exhaust the airflow at an airflow outlet 124b to the external environment. In this way, the temperature of the laser compression bonding device 100 can be further decreased if desired.

In some embodiments, the liquid channel 118 of the heat spreader 116 may contain a heating liquid to heat the transparent compression head 106, for example, when the temperature of the transparent compression head 106 is too low to implement the bonding process. It can be appreciated that whether the liquid flowing inside the liquid channel 118 acts as a cooling liquid or a heating liquid for heat exchange mainly depends on a difference in temperature between the liquid supplied into the liquid channel 118 and the transparent compression head 106. Furthermore, in some embodiments, one or more temperature sensors may be attached to the transparent compression head 106, e.g., close to its central portion, to detect the temperature of the transparent compression head 106. As such, the temperature sensors may generate temperature measurements and provide them to a controller, based on which the controller may determine whether to supply a cooling liquid or a heating liquid into the liquid channel 118. If the temperature measurement is lower than a predetermined temperature range or particularly a lower limit of the predetermined temperature range, the heating liquid may be supplied into the liquid channel 118; and if the temperature measurement is higher than the predetermined temperature range or particularly an upper limit of the predetermined temperature range, the cooling liquid may be supplied into the liquid channel 118.

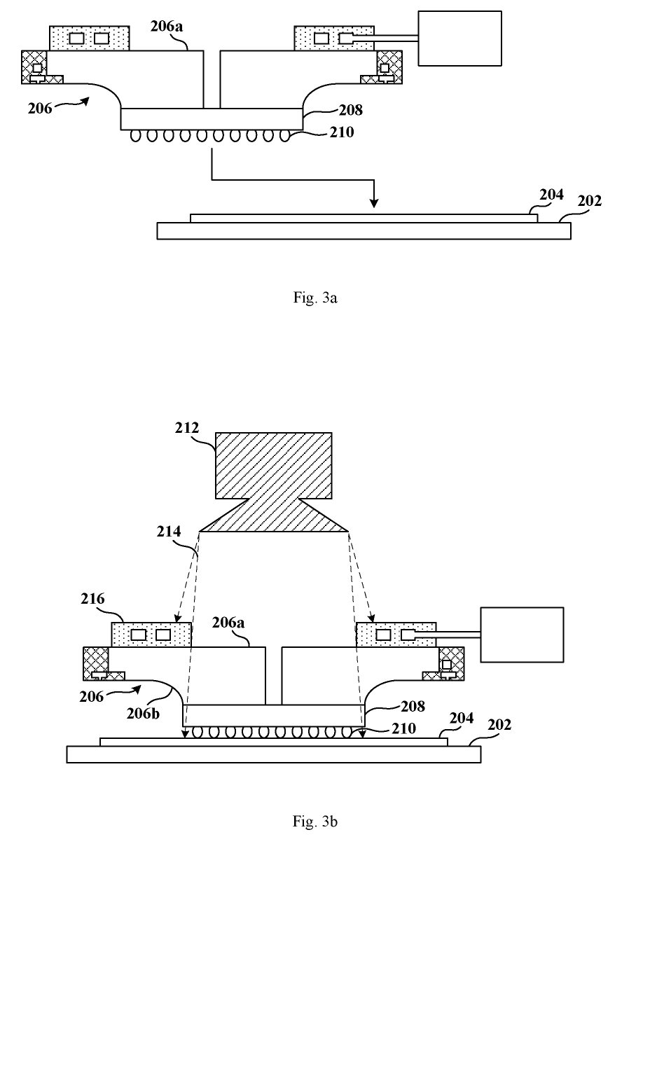

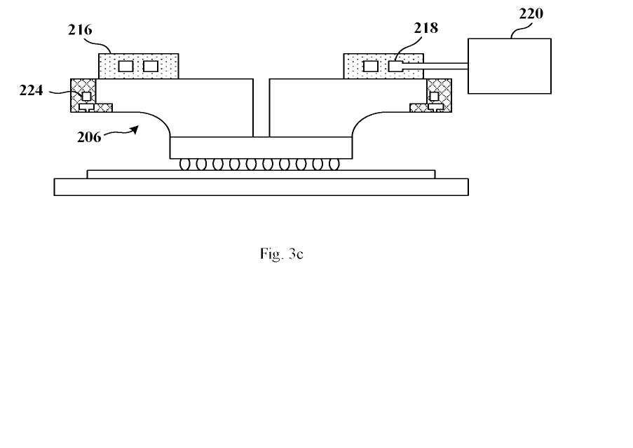

FIGS. 3a to 3c illustrates a laser compression bonding method according to an embodiment of the present application. In some embodiments, the laser compression bonding method may be implemented by the laser compression bonding device 100 shown in FIGS. 2a and 2b.

As shown in FIG. 3a, a substrate 204 may be placed on a carrier 202. Further, an electronic component 208 may be picked up by a transparent compression head 206, for example, attached to a central portion 206a of the transparent compression head 206. A solder material 210 may be formed on a back surface of the electronic component 208, or alternatively formed on a front surface of the substrate 204. The transparent compression head 206 may move to place the electronic component 208 on the substrate 204 via the solder material 210.

Next, as shown in FIG. 3b, a laser source 212 may be moved to a position above the transparent compression head 206. When the electronic component 208 is in place on the substrate 204, the electronic component 208 can be pressed against the substrate 204 by the transparent compression head 206. Furthermore, a laser beam 214 may be irradiated to the carrier 202 from the laser source 212. The laser beam 214 may pass through the central portion 206a of the transparent compression head 206 to bond the electronic component 208 onto the substrate 204 via the solder material 210. Depending on the amount and composition of the solder material 210, the emission of the laser beam 214 may be configured or adjusted to supply sufficient energy to the solder material 210, which will not be elaborated in details. Although a heat spreader 216 may be attached to a peripheral portion 206b of the transparent compression head 206, the heat spreader 216 may have an aperture that is generally aligned with and greater than the central portion 206a of the transparent compression head 206. Thus, the heat spreader 216 may at least not affect the transmission of the laser beam 214 to the electronic component 208 and the solder material 210 thereunder.

Next, as shown in FIG. 3c, after the laser compression bonding process, the temperature of the transparent compression head 206 may increase significantly. Accordingly, a liquid may be injected from a liquid supply 220 into the heat spreader 216 or particularly into a liquid channel 218 in the heat spreader 216, to cool the transparent compression head 206. After heat exchange between the liquid in the liquid channel 218 and the transparent compression head 206, the liquid can be drawn from the liquid channel 218. In some embodiments, a cooling airflow may be supply into an airflow channel 224 attached to an outside edge of the transparent compression head 206 to assist the cooling of the transparent compression head 206. In this way, the temperature of the transparent compression head 206 may be maintained within a predetermined range as desired.

In some embodiments, the cooling liquid, or a heating liquid, may be continuously or intermittently supplied into the liquid channel 218 before, during and after the laser compression bonding process. The liquid can exchange heat with the transparent compression head 206 so as to adjust the temperature of the transparent compression head 206 as desired.

The discussion herein includes numerous illustrative figures that show various portions of a laser compression bonding device and a laser compression bonding method implemented by the same. For illustrative clarity, such figures do not show all aspects of each exemplary method. Any of the example methods provided herein may share any or all characteristics with any or all other methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A laser compression bonding device, comprising:
a carrier for placing a substrate;
a transparent compression head for holding and displacing an electronic component, wherein the transparent compression head comprises a central portion for pressing the electronic component against the substrate via a solder material when the electronic component is placed on the substrate via the solder material, and a peripheral portion surrounding the central portion;
a laser source for emitting a laser beam towards the carrier at least through the central portion of the transparent compression head to heat the solder material such that the electronic component is bonded onto the substrate via the solder material; and
a heat spreader attached to the peripheral portion of the transparent compression head, wherein the heat spreader comprises a liquid channel for containing liquid that flows in the liquid channel to exchange heat with the transparent compression head.

2. The laser compression bonding device of claim 1, wherein the heat spreader is surrounding the central portion of the transparent compression head.

3. The laser compression bonding device of claim 1, wherein the liquid is a cooling liquid for cooling the transparent compression head.

4. The laser compression bonding device of claim 1, wherein the liquid comprises a cooling liquid for cooling the transparent compression head or a heating liquid for heating the transparent compression head.

5. The laser compression bonding device of claim 1, further comprising:
a liquid supply that is fluidly coupled to the liquid channel to supply liquid into the liquid channel and draw liquid from the liquid channel after heat exchange between the liquid in the liquid channel and the transparent compression head.

6. The laser compression bonding device of claim 1, wherein the transparent compression head comprises a front surface facing towards the laser source and a back surface opposite to the front surface, and wherein the heat spreader is attached on the front surface or the back surface of the transparent compression head.

7. The laser compression bonding device of claim 1, wherein the transparent compression head comprises a front surface facing towards the laser source and a back surface opposite to the front surface, and wherein the heat spreader is attached on the front surface and the back surface of the transparent compression head.

8. The laser compression bonding device of claim 1, wherein the heat spreader is formed of a non-transparent material.

9. The laser compression bonding device of claim 8, wherein the heat spreader is arranged such that the laser beam is blocked by the heat spreader from irradiating onto a peripheral region of the substrate without the solder material.

10. The laser compression bonding device of claim 1, wherein the heat spreader is formed of a transparent material.

11. The laser compression bonding device of claim 1, wherein the transparent compression head further comprises at least one through hole passing through its central portion to apply a vacuum pressure to the electronic component to hold the electronic component.

12. The laser compression bonding device of claim 1, wherein the transparent compression head further comprises an airflow channel attached to an outside edge of the transparent compression head, and wherein the airflow channel is configured to contain a cooling airflow for cooling the transparent compression head.

13. A laser compression bonding method, comprising:
placing a substrate on a carrier;
placing by a transparent compression head an electronic component on the substrate via a solder material;
pressing the electronic component against the substrate by the transparent compression head and irradiating to the carrier a laser beam from a laser source through the central portion of the transparent compression head to bond the electronic component onto the substrate via the solder material; and
injecting a liquid into a heat spreader attached to a peripheral portion of the transparent compression head to cool the transparent compression head, wherein the peripheral portion is surrounding the central portion and the heat spreader comprises a liquid channel;
drawing the liquid from the liquid channel after heat exchange between the liquid and the transparent compression head.
